(19) United States
(12) Patent Application Publication
(10) Pub. No.: US 2024/0074102 A1
(43) Pub. Date: Feb. 29, 2024

(54) Immersion Cooling Cabinet

(71) Applicant: Green Revolution Cooling, Inc., Austin, TX (US)

(72) Inventor: Alex David McManis, Austin, TX (US)

(21) Appl. No.: 17/900,541

(22) Filed: Aug. 31, 2022

(51) Int. Cl. H05K 7/20

(52) U.S. Cl. CPC H05K 7/20272; H05K 7/20236; H05K 7/20772

(57) ABSTRACT

Various aspects include devices, systems, and methods for providing support for an immersion coolant tank drawer with a support bracket. The support bracket includes a slide bar having a proximal end and a distal end. The proximal end is mounted to the immersion cooling cabinet below a lower edge of the immersion coolant tank drawer. The slide bar is configured to extend from the proximal end to the distal end away from the immersion cooling cabinet in a direction the immersion coolant tank drawer slides horizontally. The slide bar is configured to engage the immersion coolant tank drawer while the immersion coolant tank drawer slides along the slide bar. In addition, the support bracket includes an engagement element coupled to the distal end of the slide bar, wherein the engagement element is a load-bearing member.

### BACKGROUND

Immersion cooling racks provide a bath of dielectric coolant fluid in a tank. The dielectric coolant fluid may be circulated such that heat from one or more computer servers mounted within the immersion cooling racks may be rejected from the fluid to the atmosphere (typically via an external cooling device such as an evaporative cooling tower) and cool fluid may then be delivered to the heat-generating electronic components (e.g., one or more computer servers) that would otherwise overheat.

Immersion cooling of computer servers typically provide access (e.g., for maintenance) to one side of the computer server (i.e., the top). The ideal side of the computer server to be facing up is the side with the majority of input/output (I/O) ports and/or whatever side requires the most frequent servicing. To increase the number of computer servers that may be maintained in a small area, immersion cooling racks are often designed in the form of an immersion cooling cabinet with drawers. Each drawer may hold a number of computer servers and although drawers may be vertically arranged, pulling out horizontally any one of the drawers provides access to a set of computer servers therein. However, unlike conventional cabinets with drawers, each drawer in an immersion cooling cabinet not only contains electronic equipment (e.g., numerous computer servers) but is also filled with dielectric fluid, which means each drawer is extremely heavy. As a drawer may be moved from a center of gravity of the immersion cooling cabinet, the drawer effectively becomes a moment arm. This moment arm coupled with the force due to the weight of the full drawer generates significant leverage and may tip over the immersion cooling cabinet. In addition, the moment arm applies a high torque that may overstress the immersion cooling cabinet. Thus, tall immersion cooling cabinets with drawers are generally fastened at the bottom to the floor or from behind to an adjacent wall to prevent them from tipping over when a drawer is opened.

### SUMMARY

Various aspects include devices, systems, and methods for preventing an immersion cooling cabinet with vertically stacked drawers from tipping and avoid applying large cantilever loads onto the drawer in order to reduce rack strength requirements. The systems, methods, and devices of the present invention include a support bracket for an immersion coolant tank drawer configured to slide horizontally in and out of an immersion cooling cabinet, the support bracket comprising a slide bar having a proximal end and a distal end. The proximal end may be mounted to the immersion cooling cabinet below a lower edge of the immersion coolant tank drawer. The slide bar may be configured to extend from the proximal end to the distal end away from the immersion cooling cabinet in a direction the immersion coolant tank drawer slides horizontally. The slide bar may be configured to engage the immersion coolant tank drawer while the immersion coolant tank drawer slides along the slide bar. The support bracket also includes an engagement element coupled to the distal end of the slide bar. The engagement element may be a load-bearing member.

In the systems, methods, and devices of the various embodiments the proximal end of the slide bar is pivotally mounted to the immersion cooling cabinet enabling the slide bar to pivot between a stowed orientation and a deployed orientation. In an aspect, the slide bar may pivot vertically between the stowed and deployed orientations. In an aspect, the slide bar may pivot horizontally between the stowed and deployed orientations. In an aspect, the slide bar may extend vertically in the stowed orientation and horizontally in the deployed orientation. The distal end of the slide bar may be pivotally mounted to the engagement element enabling the slide bar to pivot relative to the engagement element. The engagement element may include a support bar that extends from the pivotal mount with the slide bar toward a floor supporting the immersion cooling cabinet. The slide bar may include a first and second slide bar spaced apart from one another laterally relative to the direction the immersion coolant tank drawer slides. The engagement element may be integrally formed into the distal end of the slide bar and configured to engage an adjacent structure providing support for the slide bar. The adjacent structure may be another immersion cooling cabinet. The slide bar may be configured to engage another immersion coolant tank drawer from the other immersion cooling cabinet while the other immersion coolant tank drawer slides along the slide bar.

Some embodiments may include a support bracket for vertically stacked immersion coolant tank drawers each configured to slide horizontally in and out of an immersion cooling cabinet. The support bracket may include a first slide bar having a first proximal end and a first distal end. The first proximal end of the first slide bar may be mounted to the immersion cooling cabinet below a first edge of a first immersion coolant tank drawer of the vertically stacked immersion coolant tank drawers. The first slide bar may be configured to extend from the first proximal end to the first distal end away from the immersion cooling cabinet in a direction the first immersion coolant tank drawer slides horizontally. The first slide bar may be configured to engage the first immersion coolant tank drawer while the first immersion coolant tank drawer slides along the first slide bar. A first engagement element may be coupled to the first distal end of the first slide bar. The first engagement element may include a direct load-bearing contact point to a floor supporting the immersion cooling cabinet A second slide bar may have a second proximal end and a second distal end. The second proximal end may be mounted to the immersion cooling cabinet below a lower edge of a second immersion coolant tank drawer of the vertically stacked immersion coolant tank drawers. The second slide bar may be configured to extend from the second proximal end to the second distal end away from the immersion cooling cabinet in a direction the second immersion coolant tank drawer slides horizontally. The second slide bar may be configured to engage the second immersion coolant tank drawer while the second immersion coolant tank drawer slides along the second slide bar. A second engagement element may be coupled to the second distal end of the second slide bar. The second engagement element may include a second direct load-bearing contact point to the first slide bar.

In some embodiments, the first proximal end of the first slide bar may be pivotally mounted to the immersion cooling cabinet enabling the first slide bar to pivot between a stowed orientation and a deployed orientation. The first slide bar may extend vertically in the stowed orientation and horizontally in the deployed orientation.

Some embodiments may include an immersion cooling system, including a first immersion cooling cabinet including two or more first immersion coolant tank drawers vertically stacked. Each of the two or more first immersion coolant tank drawers may be configured to slide horizontally between a closed orientation within the first immersion cooling cabinet and an open position at least partially outside the first immersion cooling cabinet. A second immersion cooling cabinet may include two or more second immersion coolant tank drawers vertically stacked. Each of the two or more second immersion coolant tank drawers may be configured to slide horizontally between a closed position within the second immersion cooling cabinet and an open position at least partially outside the second immersion cooling cabinet. A slide bar may be configured to form a bridge between the first and second immersion cooling cabinets. At least one of the two or more first immersion coolant tank drawers or the two or more second immersion coolant tank drawers may be configured to engage and be supported by the slide bar while sliding between the closed and open positions.

In some embodiments, the slide bar may include a first and second slide bar spaced apart from one another laterally relative to a direction in which the first and second immersion coolant tank drawers are configured to slide. The slide bar may be configured to support both one of the two or more first immersion coolant tank drawers and one of the two or more second immersion coolant tank drawers. The first and second immersion coolant tank drawers may be disposed directly across from one another.

These and other features, advantages, and objects of the present invention will be further understood and appreciated by those skilled in the art by reference to the following specification, claims, and appended drawings.

### BRIEF DESCRIPTION OF THE DRAWINGS

The accompanying drawings, which are incorporated herein and constitute part of this specification, illustrate exemplary embodiments of the claims and together with the general description given above and the detailed description given below, serve to explain the features of the claims.

FIG. 1A is a perspective view of a series of immersion cooling cabinets with vertically stacked drawers and paired support brackets in various configurations in accordance with various embodiments.

FIG. 1B is a perspective view of the series of immersion cooling cabinets of FIG. 1A with two immersion coolant tank drawers in open positions and supported by paired support brackets, in accordance with various embodiments.

FIG. 1C is an isolation view of one of the series of immersion cooling cabinets of FIGS. 1A and 1B with a paired support bracket partially deployed, in accordance with various embodiments.

FIG. 1D is an isolation view of one of the series of immersion cooling cabinets of FIGS. 1A-1C with all paired support brackets fully deployed, in accordance with various embodiments.

FIG. 2A is a perspective view an immersion cooling cabinet with vertically stacked drawers with a single support bracket partially deployed in accordance with various embodiments.

FIG. 2B is a perspective view of the immersion cooling cabinet of FIG. 2A with the single support bracket fully deployed in accordance with various embodiments.

FIG. 2C is a perspective view of the immersion cooling cabinet of FIGS. 2A and 2B with a second single support bracket fully deployed in accordance with various embodiments.

FIG. 2D is a perspective view of the immersion cooling cabinet of FIGS. 2A-2C with an upper immersion coolant tank drawer in an open position and supported by the single support brackets in accordance with various embodiments.

FIG. 3A is a perspective view a series of immersion cooling cabinets with vertically stacked drawers with one set of multi-level support brackets partially deployed in accordance with various embodiments.

FIG. 3B is a perspective view of the series of immersion cooling cabinets of FIG. 3A with the one of the multi-level support brackets fully deployed and supporting an upper-level drawer, in accordance with various embodiments.

FIG. 3C is an isolation view of the fully deployed multi-level support bracket supporting the upper-level drawer, in accordance with various embodiments.

FIG. 3D is an isolation view of one of the series of immersion cooling cabinets of FIGS. 3A-3C with the fully deployed multi-level support bracket supporting a middle level drawer, in accordance with various embodiments.

FIG. 4A is a perspective view of two rows of immersion cooling cabinets facing one another in accordance with various embodiments.

FIG. 4B is a perspective view of the two rows of immersion cooling cabinets of FIG. 4A with a slide bar bridge in accordance with various embodiments.

FIG. 4C is a perspective view of the two rows of immersion cooling cabinets of FIGS. 4A and 4B with the slide bar bridge supporting an immersion coolant tank drawer in accordance with various embodiments.

FIG. 5A is a perspective view an immersion cooling cabinet with vertically stacked drawers with paired triangular support brackets in accordance with various embodiments.

FIG. 5B is a perspective view of the immersion cooling cabinet of FIG. 5A with one paired triangular support bracket fully deployed in accordance with various embodiments.

FIG. 5C is a perspective view of the immersion cooling cabinet of FIGS. 5A and 5B with the one deployed paired triangular support bracket supporting an immersion coolant tank drawer in accordance with various embodiments.

### DETAILED DESCRIPTION

Various embodiments will be described in detail with reference to the accompanying drawings. Wherever possible, the same reference numbers will be used throughout the drawings to refer to the same or like parts. References made to particular examples and implementations are for illustrative purposes and are not intended to limit the scope of the claims.

Various embodiments disclosed herein include immersion coolant tank drawer support brackets that include a slide bar having one end mounted to the immersion cooling cabinet below a lower edge of the immersion coolant tank drawer. The slide bar may be configured to extend from the one end to an opposite end away from the immersion cooling cabinet in a direction the drawer slides (i.e., horizontally). The slide bar may be configured to engage and support the immersion coolant tank drawer from an underside thereof while the immersion coolant tank drawer slides along the slide bar. In addition, the support bracket may include an engagement element coupled to the opposite end that is a load-bearing element, such as a contact point to the floor, another slide bar, and/or an adjacent structure.

Various embodiments compensate for extreme torque imparted on an immersion cooling cabinet due to the heavy weight of the drawers full of equipment and dielectric fluid. By providing one or more slide bars and engagement elements, various embodiments may address such extreme torque and reduce the structural strength requirement of the immersion cooling cabinet itself. In addition, various embodiments help prevent the immersion cooling cabinet from tipping.

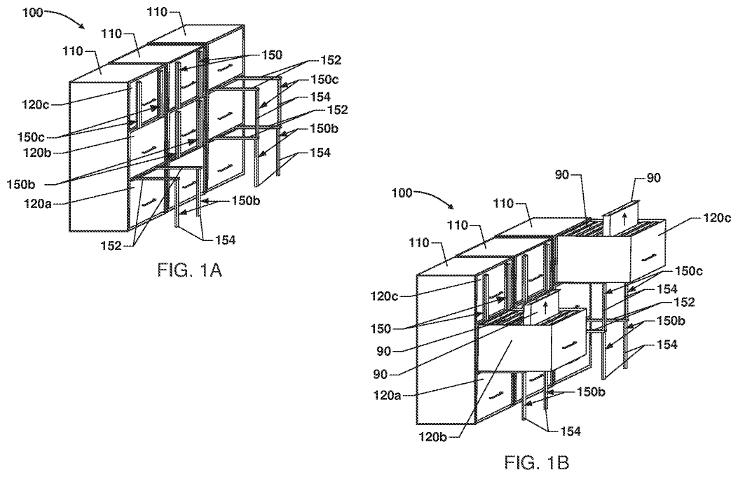

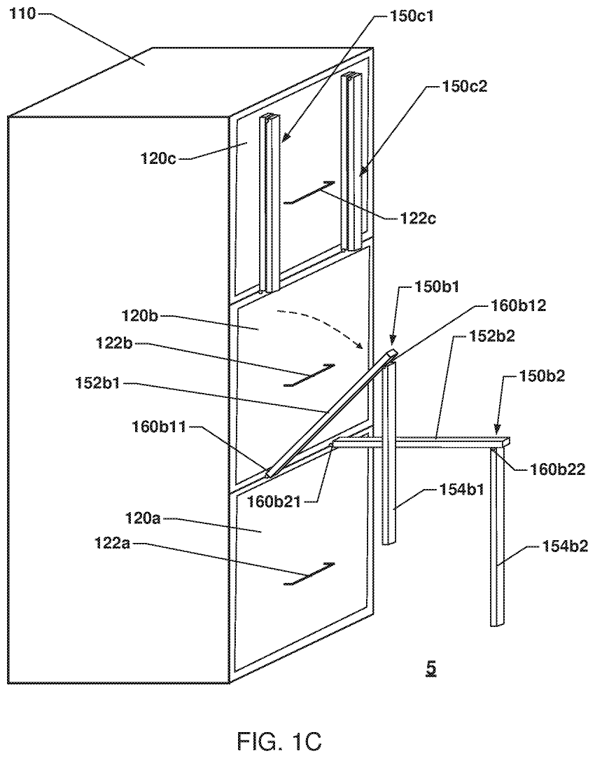

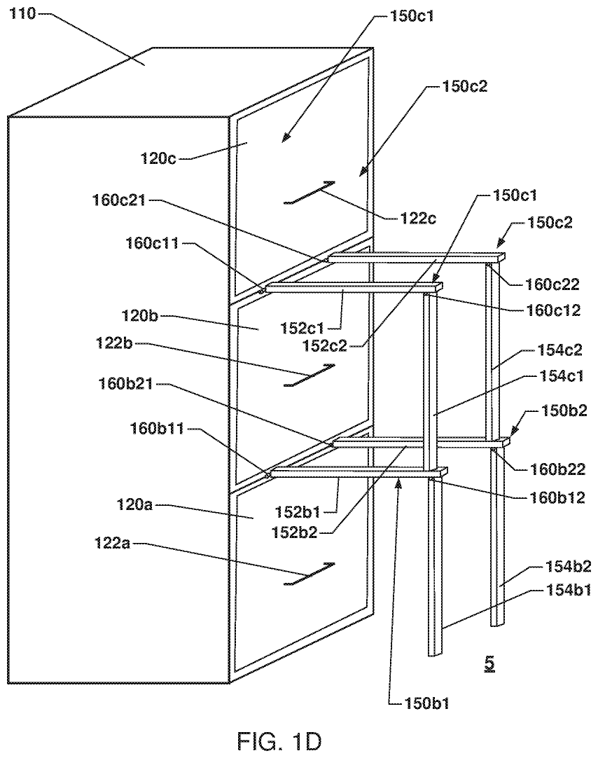

FIGS. 1A-1D illustrate various aspects of paired support brackets 150 for immersion cooling cabinets 110 with vertically stacked drawers 120a, 120b, 120c in accordance with various embodiments. The various embodiments are described herein with regard to devices, systems, and methods for preventing the immersion cooling cabinets 110 from tipping. Various embodiments apply to immersion coolant tank drawers 120a, 120b, 120c that hold dielectric fluid and one or more computer servers (e.g., 90) at least partially submerged in that dielectric fluid. Each computer server 90 (also referred to simply as server 90) may be removed vertically from the immersion coolant tank drawer 120a, 120b, 120c in which it is mounted when the immersion coolant tank drawer 120a, 120b, 120c is open.

FIGS. 1A-1B illustrate a series 100 of immersion cooling cabinets 110 (also referred to simply as an immersion cooling cabinet 110) with paired support brackets 150 in accordance with various embodiments. Paired support brackets 150 may be applied to any number of immersion cooling cabinets 110. The immersion cooling cabinets 110 may each include three immersion coolant tank drawers 120a, 120b, 120c that are arranged vertically (i.e., vertically stacked). Alternatively, the immersion cooling cabinets 110 may have only two immersion coolant tank drawers 120a, 120b, 120c or greater than three immersion coolant tank drawers 120a, 120b, 120c, depending on the design parameters of the immersion cooling cabinets 110. In some embodiments, the immersion cooling cabinets 110 may include more or less immersion coolant tank drawers 120a, 120b, 120c. Each of the immersion coolant tank drawers 120a, 120b, 120c may be configured to slide horizontally in and out of an immersion cooling cabinet 110 between an open and closed position.

Due to the heavy weight of each of the immersion coolant tank drawers 120a, 120b, 120c, the middle level drawers 120b and upper level drawers 120c pose the biggest threat of tipping over their respective immersion cooling cabinet 110. Thus, various embodiments mount the paired support brackets 150 just below the middle level drawers 120b and the upper level drawers 120c. While the bottom level drawers 120a may also use some vertical support to keep them from tipping forward or tipping the entire immersion cooling cabinet 110 forward, unlike the middle and upper drawers, the bottom level drawers 120a may be outfitted with rollers or other support structures since no other drawer is below the bottom level drawers 120a.

In FIG. 1A, each of the immersion cooling cabinets 110 includes pairs of paired support brackets (150b, 150c) mounted below a lower edge of the middle level drawers 120b and upper level drawers 120c. Each pair of the paired support brackets 150b, 150c may include two brackets that work together to support an immersion coolant tank drawer (e.g., middle level drawer 120b and/or upper level drawer 120c). Each of the paired support bracket (150b, 150c) may be defined by a slide bar 152 and an engagement element 154. The slide bar 152 may be mounted at a first end, which may be referred to as a proximal end, to the immersion cooling cabinet 110, below a lower edge of the respective immersion coolant tank drawer 120b, 120c. The slide bar 152 extends from the proximal end to second end, which may be referred to as a distal end that is opposed to the proximal end. The slide bar 152 may be mounted at the distal end to the engagement element 154. In some embodiments, the slide bar 152 may be pivotally mounted at the distal end to the engagement element 154. An end of the engagement element 154 not coupled to the slide bar 152 may be configured to be a load-bearing member. Thus, the engagement element 154 may provide a contact point to the floor, another slide bar 152, or an adjacent structure.

Each of the support brackets (150b, 150c) may be configured to move between a stowed orientation and a deployed orientation. In the stowed orientation the slide bar 152 may extend vertically upward from its pivotal mount with the immersion cooling cabinet 110 across a front face of the immersion coolant tank drawer 120b, 120c. Similarly, in the stowed orientation, the engagement element 154 extends vertically downward from its pivotal mount with the slide bar 152. In some embodiments, the engagement element includes or is formed as a support bar that extends from the pivotal mount with the slide bar 152 toward a floor supporting the immersion cooling cabinet 100. Each support bracket 150 and/or the outer face of the immersion coolant tank drawer 120b, 120c may include a clip, pin, or other fastener configured to hold the support bracket 150 in the stowed orientation. In the deployed orientation, the slide bar 152 may extend from the proximal end to the distal end away from the immersion cooling cabinet 110. In particular, in a fully deployed orientation, the slide bar 152 may extend from the proximal end to the distal end away from the immersion cooling cabinet 110 in a direction the immersion coolant tank drawer 120b, 120c slides horizontally. Also, in the deployed orientation, the slide bar 152 may be configured to engage the immersion coolant tank drawer 120b, 120c while that immersion coolant tank drawer 120b, 120c slides along the slide bar 152.

In FIGS. 1A and 1B, each of the immersion cooling cabinet 110 includes two pairs of paired support brackets (150b, 150c), with one pair of paired support brackets 150c on each respective top level drawer 120c and one pair of support brackets 150b on each respective middle level drawers 120b. Also shown are three pairs of paired support brackets (150b, 150c) in a deployed orientation; one pair of paired support brackets 150b on the middle level drawer 120b closest to the foreground; one pair of paired support brackets 150c on the top level drawer 120c closest to the background; and one pair of paired support brackets 150b on the middle level drawer 120b closest to the background.

FIG. 1B also illustrates two immersion coolant tank drawers 120b and 120c open, namely one middle level drawer 120b closest to the foreground and one top level drawer 120c closest to the background. In the open position, the middle level drawer 120b (i.e., closest to the foreground in the orientation shown) is supported by the pair of paired support brackets 150b directly thereunder. In contrast, in the open position, the top level drawer 120c (i.e., closest to the background in the orientation shown) is supported by two pairs of paired support brackets 150b and 150c. In particular, the pairs of paired support brackets 150b, 150c on the top level drawers 120c, when fully deployed, are configured to directly contact, and be supported by the pairs of paired support brackets 150b, 150c on the middle level drawers 120b directly below. Thus, the top level paired support brackets 150c may utilize the middle level paired support brackets 150b directly below to also be deployed in order to provide a weight-bearing support for the top level drawers 120c.

FIGS. 1C and 1D illustrate one of the series of immersion cooling cabinets 110 of FIGS. 1A and 1B in isolation. In accordance with various embodiments, each of the paired support brackets (e.g., 150b1/150b2 and 150c1/150c2) may include first and second slide bars (e.g., 152b1/152b2 and 152c1/152c2), which may be spaced apart from one another laterally relative to the direction the immersion coolant tank drawers (e.g., 120b, 120c) slides. In particular, the middle and top level immersion coolant tank drawers 120b, 120c include middle level left paired support bracket 150b1, top level left support bracket 150c1, middle level right paired support bracket 150b2, and top level right paired support bracket 150c2, which are distinguished/identified by different reference numbers in order to explain how the paired support brackets (e.g., 150b, 150c) operate. In various embodiments, the middle level left paired support bracket 150b1, top level left support bracket 150c1, middle level right paired support bracket 150b2, and top level right paired support bracket 150c2 may pivot independent from one another.

In FIG. 1C the pair of top level paired support brackets 150c1, 150c2 are illustrated in a stowed orientation; a middle level left support bracket 150b1 is shown moving between the stowed and deployed configurations; and a middle level right support bracket 150b2 is shown in the fully deployed configuration.

To move a support bracket (e.g., 150b1, 150b2, 150c1, 150c2) between a stowed and a deployed configuration, the support bracket may pivot relative to the immersion cooling cabinet 100. A face of the middle and/or top level immersion coolant tank drawers 120b, 120c may include a lock or fastening element that is configured to hold the support bracket (e.g., 150b1, 150b2, 150c1, 150c2) in the stowed configuration.

When deploying the middle level support brackets 150b1, 150b2, once released from the stowed configuration, a middle level slide bar 152b1, 152b2 may be pivoted (e.g., manually or automated) from a vertical orientation toward a horizontal orientation. For example, the middle level left support bracket 150b1 may include a middle level left slide bar 152b1, a middle level first left hinge 160b11, a middle level second left hinge 160b12, and a middle level left engagement element 154b1. Similarly, the middle level right support bracket 150b2 may include a middle level right slide bar 152b2, a middle level first right hinge 160b21, a middle level second right hinge 160b22, and a middle level right engagement element 154b2. The middle level first hinges 160b11, 160b21 may pivotally couple the middle level slide bars 152b1, 152b2, respectively, to the immersion cooling cabinet 110, enabling independent pivotal movement of the middle level slide bars 152b1, 152b2 relative to the immersion cooling cabinet 110 and one another. As each middle level slide bar 152b1, 152b2 pivots toward a horizontal orientation, the middle level engagement element 154b1, 154b2 may remain vertical, dangling as a result of the middle level second hinges 160b12, 106b22 coupling the middle level engagement elements 154b1, 154b2 to the middle level slide bars 152b1, 152b2, respectively. Once the middle level slide bars 152b1, 152b2 reach a horizontal orientation, the middle level engagement element 154b1, 154b2 may be sized and positioned to reach the floor 5. With a bottom of the middle level engagement element 154b1, 154b2 contacting the floor 5, that bottom will provide a direct load-bearing contact point with the floor 5. In this way, the middle level slide bars 152b1, 152b2 may have a load bearing support for the middle level drawer 120b at both ends; one at the middle level first hinge 160b11, 160b21 and the other at the middle level second hinge 160b12, 160b22. With the middle level paired support brackets 150b1, 150b2 in a deployed configuration, the middle level drawer 120b may open in a horizontal direction and be supported by the middle level slide bars 152b1, 152b2. A bottom surface of the middle level drawer 120b may be configured to engage and ride along the horizontally oriented middle level slide bars 152b1, 152b2. Alternatively, a bottom of the middle level drawer 120b may include a channel or guide that is configured to receive the middle level slide bars 152b1, 152b2 and guide/stabilize the movement thereon.

In FIG. 1D the pair of top level paired support brackets 150c1, 150c2 are illustrated in a deployed orientation, as well as both middle level support bracket 150b1, 150b2. During deployment, the top level support brackets 150c1, 150c2, once released from the stowed configuration, a top level slide bar 152c1, 152c2 may be pivoted (e.g., manually) from a vertical orientation toward a horizontal orientation. For example, the top level left support bracket 150c1 may include a top level left slide bar 152c1, a top level first left hinge 160c11, a top level second left hinge 160c12, and a top level left engagement element 154c1. Similarly, the top level right support bracket 150c2 may include a top level right slide bar 152c2, a top level first right hinge 160c21, a top level second right hinge 160c22, and a top level right engagement element 154c2. The top level first hinges 160c11, 160c21 may pivotally couple the top level slide bars 152c1, 152c2, respectively, to the immersion cooling cabinet 110, enabling independent pivotal movement of the top level slide bars 152c1, 152c2 relative to the immersion cooling cabinet 110 and one another. As each top level slide bar 152c1, 152c2 pivots toward a horizontal orientation, the top level engagement element 154c1, 154c2 may remain vertical, dangling as a result of the top level second hinges 160c12, 106c22 coupling the top level engagement elements 154c1, 154c2 to the top level slide bars 152c1, 152c2, respectively. Once the top level slide bars 152c1, 152c2 reach a horizontal orientation, the top level engagement elements 154c1, 154c2 may be sized and positioned to reach the already fully deployed middle level slide bars 152b1, 152b2. In this way, with a bottom of the top level engagement elements 154c1, 154c2 contacting the middle level slide bars 152b1, 152b2, which are in-turn supported by the floor 5, the bottom of the top level engagement elements 154c1, 154c2 will provide a direct load-bearing contact point with a top surface of the middle level slide bars 152b1, 152b2. In this way, the top level slide bars 152c1, 152c2 may have a load bearing support for the top level drawer 120c at both ends; one at the top level first hinges 160c11, 160c21 and the other at the top level second hinges 160c12, 160c22. With the top level paired support brackets 150c1, 150c2 in a deployed configuration, the top level drawer 120c may open in a horizontal direction and be supported by the top level slide bars 152c1, 152c2. In this manner, the load of the open top level drawer 120c may be transferred and supported by the deployed top level support brackets 150c1, 1502 that are in turn supported by deployed middle level support brackets 150b1, 150b2. Also, a bottom surface of the top level drawer 120c may be configured to engage and ride along the horizontally oriented top level slide bars 152c1, 152c2. Alternatively, a bottom of the top level drawer 120c may include a channel or guide that is configured to receive the top level slide bars 152c1, 152c2 and guide/stabilize the movement thereon.

Each of the immersion coolant tank drawers 120a, 120b, 120c may include a handle 122a, 122b, 122c, which may be used to pull out the respective immersion coolant tank drawers 120a, 120b, 120c. For example, prior to pulling out the middle level drawer 120b, the pair of middle level paired support brackets 150b1, 150b2 should be deployed. In contrast, prior to pulling out the top level drawer 120c, the pair of middle level paired support brackets 150b1, 150b2 should be deployed, followed by the deployment of the pair of top level paired support brackets 150c1, 150c2 that will engage and rest upon the pair of slide bars 152b1, 152b2 of middle level paired support brackets 150b1, 150b2.

In some embodiments, as the drawers (e.g., 120b, 120c) are opened, the support brackets may automatically deploy the respective support brackets 150b1, 150b2, 150c1, 150c2. For example, the motion of opening the top level drawer 120c may trigger the deployment of middle level support brackets 150b1, 1502, followed by the deployment of top level support brackets 150c1, 150c2 such that middle level support brackets 150b1, 150b2 engage the floor 5 and top level support brackets 150c1, 150c2 engage the middle level slide bars 152b1, 152b2 of middle level support brackets 150b1, 1502 to support the load of the opened top level drawer 120c. Similar automatic deployment of only the middle level support brackets 150b1, 150b2 may be triggered when the middle level drawer 120b is opened. In a similar manner, the closing of the drawers 120b, 120c may trigger the stowage of the support brackets 150b1, 150b2, 150c1, 150c2.

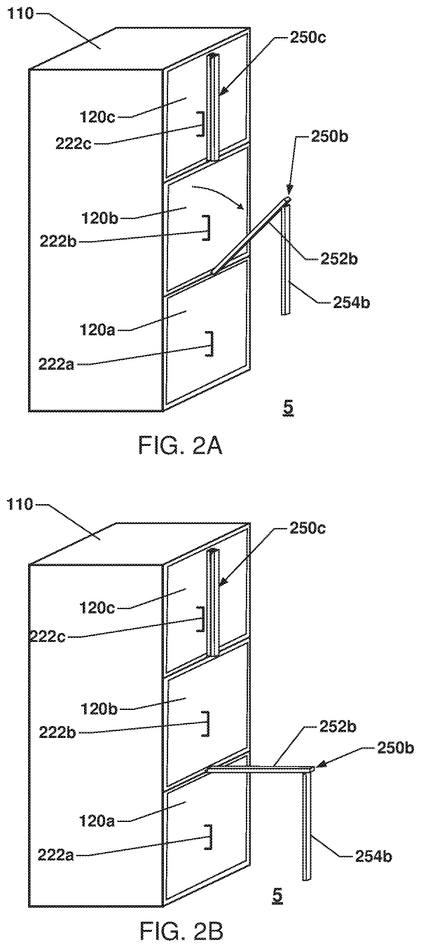

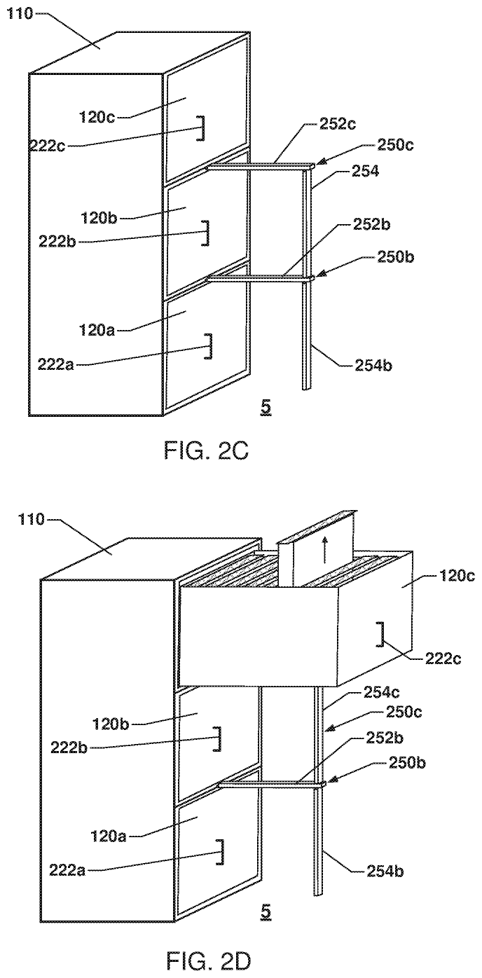

FIGS. 2A-2D illustrate single support brackets 250b, 250c (i.e., not used in pairs), configured to support the middle level immersion coolant tank drawer 120b and top level immersion coolant tank drawer 120c, respectively, in accordance with various embodiments. The single support brackets 250b, 250c may include similar features and operate in the same way as the support brackets described with regard to FIGS. 1A-1D (e.g., 150b1, 150b2, 150c1, 150c2). In order to accommodate a central position of the single support brackets 250b, 250c, the immersion coolant tank drawers 120a, 120b, 120c may include handles 222a, 222b, 222c are oriented vertically and/or otherwise repositioned as to not interfere with the operation of the single support brackets 250b, 250c.

In FIG. 2A, the top level support bracket 250c is in a stowed orientation extending vertically across the front face of the top level immersion coolant tank drawer 120c. Also, the middle level single support bracket 250b is illustrated pivoting from the stowed orientation to the fully deployed orientation (i.e., partially deployed). In the partially deployed orientation, the slide bar 252b is at an oblique angle, while the engagement element 254b hangs vertically.

In FIG. 2B, the top level single support bracket 250c is in the stowed orientation extending vertically across the front face of the top level immersion coolant tank drawer 120c. Also, the middle level single support bracket 250b is illustrated now in the fully deployed orientation (i.e., fully deployed). In the fully deployed orientation, the slide bar 252b extends horizontally away from the immersion cooling cabinet 110, while the engagement element 254b extends vertically and engages the floor 5.

In FIG. 2C, the top level single support bracket 250c is in the fully deployed orientation extending horizontally away from the immersion cooling cabinet 110. Also, the middle level single support bracket 250b is illustrated in the fully deployed orientation. When the top level single support bracket 250c is fully deployed, the top level slide bar 252c extends horizontally away from the immersion cooling cabinet 110, while the top level engagement element 254c extends vertically and engages the middle level slide bar 252b of the middle level support bracket 250b.

FIG. 2D illustrates the top level upper immersion coolant tank drawer 120c in an open position and supported by both the upper and bottom level single support brackets 250c, 250b in accordance with various embodiments.

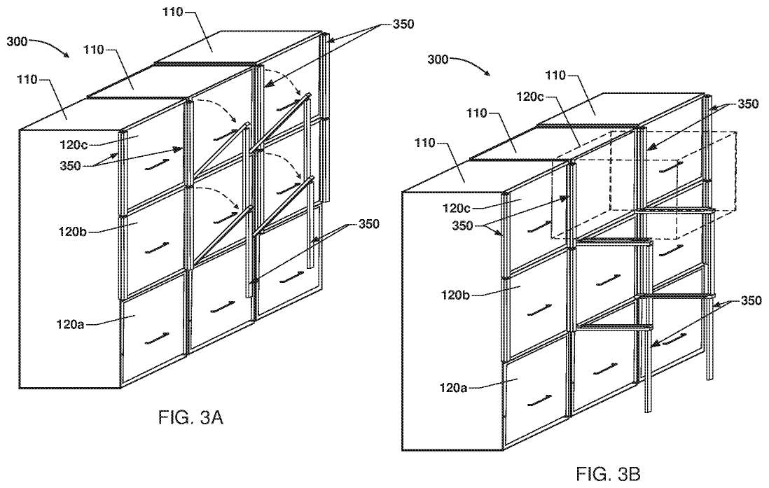

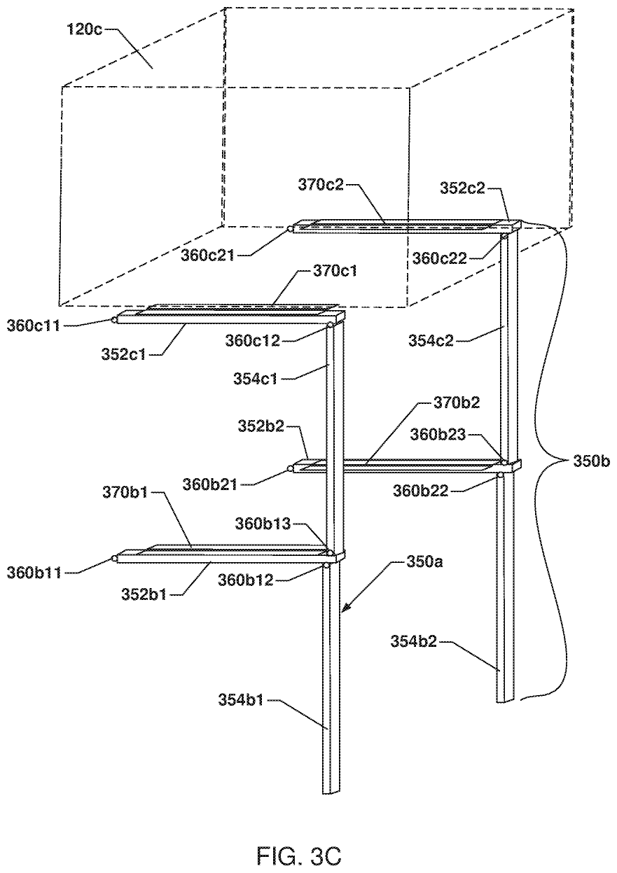

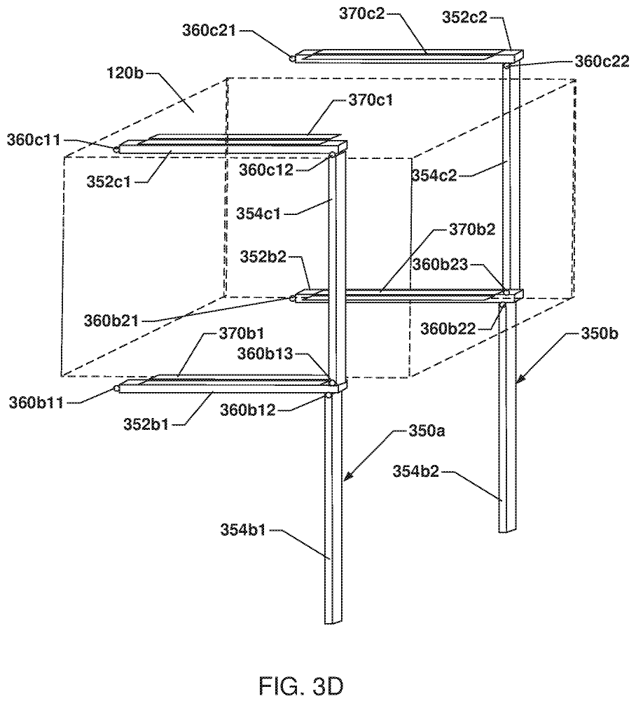

FIGS. 3A-3D illustrate various aspects of multi-level support brackets 350 for immersion cooling cabinets 110 with vertically stacked drawers 120a, 120b, 120c in accordance with various embodiments. FIGS. 3A-13 illustrate a series 300 of the immersion cooling cabinets 110 with multi-level support brackets 350 in accordance with various embodiments. The multi-level support brackets 350 may be applied to any number of immersion cooling cabinets 110. Each of the immersion cooling cabinets 110 may include pairs of multi-level support brackets 350 mounted along opposed lateral sides of the middle level and upper level immersion coolant tank drawers 120b, 120c.

In FIGS. 3A and 3B pairs of multi-level support brackets 350 flank each of the middle level and top level immersion coolant tank drawers 120b, 120c. FIG. 3A illustrates a pair of multi-level support brackets 350, flanking a middle immersion cooling cabinet 110 (of the three illustrated immersion cooling cabinets 110), in a partially deployed configuration. In particular, the partially deployed pair of multi-level support brackets 350 are halfway between the stowed orientation and the fully deployed orientation. FIG. 3B illustrates the pair of multi-level support brackets 350 in a fully deployed configuration, as well as a top immersion coolant tank drawer 120c in the open position thereon.

FIGS. 3C and 3D illustrate isolated views of one pair of multi-level support brackets 350a, 350b in accordance with various embodiments. In FIGS. 3C and 3C, each multi-level support bracket 350a, 350b and elements thereof are distinguished/identified by different reference numbers in order to explain how the pair of multi-level support brackets 350a, 350b operate. For example, a multi-level left support bracket 350a may be defined by a top level first left hinge 360c11, a top level left slide bar 352c1, a top level second left hinge 360c12, a top level left engagement element 354c1, a middle level first left hinge 360b11, a middle level left slide bar 352b1, a middle level second left hinge 360b12, a middle level third left hinge 360b13, and a middle level left engagement element 354b1. Similarly, a multi-level right support bracket 350b may be defined by a top level first right hinge 360c21, a top level right slide bar 352c2, a top level second right hinge 360c22, a top level right engagement element 354c2, a middle level first right hinge 360b21, a middle level right slide bar 352b2, a middle level second right hinge 360b22, a middle level third right hinge 360b23, and a middle level right engagement element 354b2.

The multi-level support brackets 350a, 350b may be formed like two vertically stacked paired support brackets (e.g., 150) or single support brackets (e.g., 250). For example, as shown in FIGS. 3C and 3D, each of the top slide bars 352c1, 352c2 and middle slide bars 352b1, 352b2 may be pivotally mounted by a first hinge 360b11, 360b21, 360c11, 360c21 at one end to the immersion cooling cabinet 110, just below the lower edge of the top level immersion coolant tank drawer 120c and middle level immersion coolant tank drawer 120b, respectively. Also, each of the top slide bars 352c1, 352c2 and the middle slide bars 352b1, 352b2 may be pivotally mounted by a second hinge 360b12, 360b22, 360c12, 360c22 at an opposite end to respective ones of the top level engagement elements 354c1, 354c2 and middle level engagement element 354b1, 354b2. Additionally, the upper structure (i.e., the top slide bars 352c1, 352c2 and top engagement elements 354c1, 354c2) may be pivotally coupled by the third hinge 360b13, 360b23 to the lower structure (i.e., the middle slide bars 352b1, 352b2 and lower engagement element 354b1, 354b2). In particular, an end of the top engagement elements 354c1, 354c2 not coupled to the top slide bars 352c1, 352c2 may be pivotally coupled by the third hinges 360b13, 360b232 to a top side of the middle slide bars 352b1, 352b2, respectively. In this way, the upper structure and lower structure deploy in unison.

Unlike the paired support brackets (e.g., 150) or single support brackets (e.g., 250), the pairs of multi-level support brackets 350a, 350b are illustrated as flanking a column of immersion coolant tank drawers 120b, 120c. In this way, the pairs of multi-level support brackets 350a, 350b are spaced laterally to the left and right of the immersion coolant tank drawers 120b, 120, allowing the middle level immersion coolant tank drawer 120 to slide past both pairs of multi-level support brackets 350a, 350b in the open position. As a result of this positioning, the slide bars 352b1, 352b2, 352c1, 352c2 of each of the pair of multi-level support brackets 350a, 350b will not be disposed under any of the immersion coolant tank drawers 120b, 120c when they get pulled out. Thus, as shown in FIGS. 3C and 3D, each of the multi-level support brackets 350a, 350b additionally includes support flanges 370b1, 370b2, 370c1, 370c2. Opposed pairs of the support flanges 370c1, 370c2 and 370b1, 370b2 may be configured to extend inwardly toward one another to support the immersion coolant tank drawers 120b, 120c when they open. As shown in FIGS. 3B-3D, the pair of multi-level support brackets 350a, 350b may be configured to work together to support an immersion coolant tank drawer 120b, 120c, such as a middle and/or top level immersion coolant tank drawer 120b, 120c in the open position.

In FIGS. 3C and 3D, the top level immersion coolant tank drawer 120c, in the open position, is supported on a top level of the pair of multi-level support brackets 350a, 350b by the opposed pairs of top level support flanges 370c1, 370c2. In contrast, in FIG. 3D a middle level immersion coolant tank drawer 120b, in the open position, is supported on a middle level of the pair of multi-level support brackets 350b1, 350b2 by the opposed pair of middle level support flanges 370b1, 370b2.

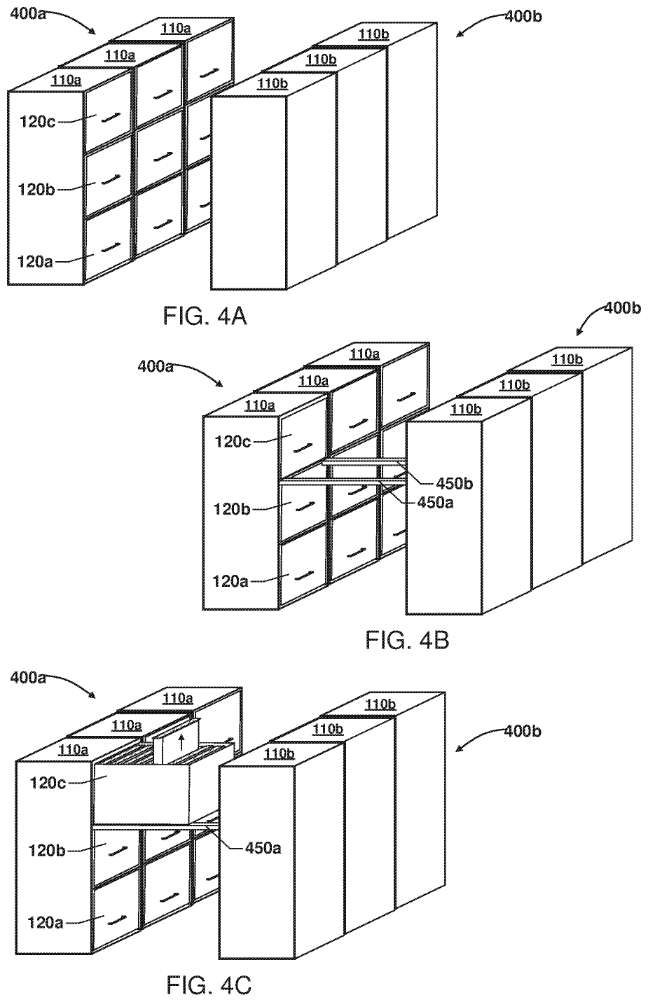

FIGS. 4A-4C illustrate bridge-style support brackets 450a, 450b in accordance with various embodiments. In FIGS. 4A-4C two rows 400a, 400b of immersion cooling cabinets 110a, 110b are illustrated facing one another. In particular, the immersion coolant tank drawers 120a, 120b, 120c from one row (e.g., a first row 400a) of immersion cooling cabinets 110 open toward the immersion coolant tank drawers (e.g., 120a, 120b, 120c) from the other row (e.g., a second row 400b) of immersion cooling cabinets 110. The bridge-style support brackets 450a, 450b may extend between opposed immersion cooling cabinets 110a, 110b to form a bridge between the first and second immersion cooling cabinets 110a, 110b. At least one of the middle and top level immersion coolant tank drawers 120b, 120c may be configured to engage and be supported by the bridge-style support brackets 450a, 450b while sliding between the closed and open positions. The bridge supports may also extend to any other structure that provides support similar to another rack. For example, the bridge supports may extend to an adjoining wall, piece of equipment, object, device, or other support structure. The other structure supporting the bridge supports may include a hook, recess, or other receiving structure configured to hold the bridge supports.

In accordance with various embodiments, a first immersion cooling cabinet 110a may include two or more first immersion coolant tank drawers 120a, 120b, 120c vertically stacked. Each of the two or more first immersion coolant tank drawers 120a, 120b, 120c may be configured to slide horizontally between a closed position within the first immersion cooling cabinet 110a and an open position at least partially outside the first immersion cooling cabinet 110a. In addition, a second immersion cooling cabinet 100b may include two or more second immersion coolant tank drawers (e.g., 120a, 120b, 120c) vertically stacked. Each of the two or more second immersion coolant tank drawers may be configured to slide horizontally between a closed position within the second immersion cooling cabinet 110b and an open position at least partially outside the second immersion cooling cabinet 110b.

The bridge-style support brackets 450a, 450b may include a slide bar portion that has a proximal end and a distal end. The proximal end of the slide bar portion may be mounted to an immersion cooling cabinet 110a in the first row 400a. The mount to the immersion cooling cabinet 110a may be below a lower edge of an immersion coolant tank drawer (e.g., 120). In addition, the bridge-style support brackets 450a, 450b may include an engagement element portion that may be coupled to or form a part of the distal end of the slide bar portion. The engagement element portion may be configured to provide a direct load-bearing contact point for the bridge-style support brackets 450a, 450b, respectively to an immersion cooling cabinet 110b in the second row 400b. One or both of the opposed immersion cooling cabinets 110a, 110b, supporting the bridge-style support brackets 450a, 450b, may include a hook, recess, or other receiving structure configured to hold the respective proximal and/or distal ends of the slide bar portions. Once mounted between opposed immersion cooling cabinets 110a, 110b, the bridge-style support brackets 450a, 450b may be considered to be in a deployed orientation in which they are configured to extend from the proximal end to the distal end away from one of the immersion cooling cabinets (e.g., 110) in a direction the immersion coolant tank drawer (e.g., 120b, 120c) slides horizontally.

Once coupled to opposing immersion cooling cabinets, the slide bar portion may be considered to be in a deployed orientation in which the slide bar portion extends from the proximal end to the distal end away from one immersion cooling cabinet (e.g., 110a) in a direction the immersion coolant tank drawer (e.g., 120) slides horizontally. In this way, the slide bar portion may be configured to engage the immersion coolant tank drawer while the immersion coolant tank drawer slides along the slide bar portion.

The immersion cooling cabinets 110a, 110b may include connection brackets just below each of the middle and top level immersion coolant tank drawers 120b, 120c. A location of the connection brackets may be similar to the middle and top level hinges (e.g., 160b11, 160b21, 160c11, 160c21, 360b11, 360b21, 360c11, 360c21) described above. The connection brackets may protrude from a front face of the immersion cooling cabinets 110a, 110b and/or include a recess for receiving an end of the at least one slide bar 450a, 450b. In this way, a first end of a slide bar 450a, 450b may be connected to a first immersion cooling cabinet 110a in the first row 400a and a second end of the same slide bar 450a, 450b may be connect to a second immersion cooling cabinet 110b in the second row 400b.

In FIG. 4B, the two rows 400a, 400b of immersion cooling cabinets 110a, 110b include a pair of slide bars 450a, 450b extending like a bridge between the two opposed immersion cooling cabinets 110a, 110b. FIG. 4C, illustrates a top level immersion coolant tank drawer 120c in an open position, protruding from the first immersion cooling cabinet 110a. In FIG. 4C, the top level immersion coolant tank drawer 120c is supported by the pair of slide bars 450a, 450b, in accordance with various embodiments. In accordance with various embodiments, a top level immersion coolant tank drawer from the second row 400b of immersion cooling cabinets 110b may similarly be configured to open and be supported by the pair of slide bars 450a, 450b. In addition, the pair of slide bars 450a, 450b may be removably mounted to the opposed immersion cooling cabinets 110a, 110b, so they may be moved to and remounted to bridge another opposing pair of immersion coolant tank drawers (e.g., 120b, 120c). The amount of space provided between the two rows 400a, 400b, which may correspond to the length of the slide bars 450a, 450b once mounted there between, may determine whether immersion coolant tank drawers from opposed rows 400a, 400b may be opened simultaneously (i.e., if there is enough space provided for both drawers to open).

Alternatively, only one slide bar 450a, 450b may be used, such as a single slide bar that extend between the two opposed immersion cooling cabinets 110a, 110b in-line with a center of the immersion coolant tank drawer (e.g., 120b, 120c). In this way, only a single slide bar 450a, 450b is used to support an immersion coolant tank drawer (e.g., 120b, 120c).

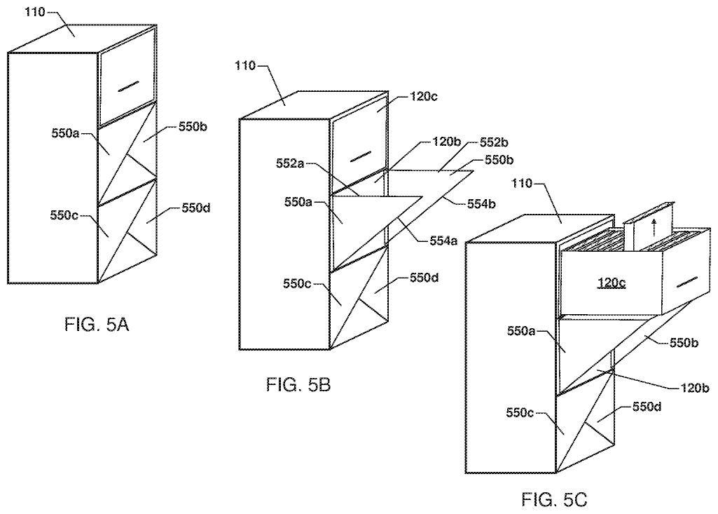

FIGS. 5A-5C illustrate paired triangular support brackets 550a, 550b, in accordance with various embodiments. Each pair of the paired triangular support brackets 550a, 550b includes two brackets that work together to support an immersion coolant tank drawer (e.g., 120b, 120c). Each of the paired triangular support brackets 550a, 550b is defined by a slide bar 552a, 552b defined by a top edge of each triangular support brackets 550a, 550b. In addition, each of the paired triangular support brackets 550a, 550b is defined by an engagement element 554a, 554b that is defined by an oblique edge, which supports the drawer weight as a load-bearing member. Thus, each of the slide bars 552a, 552b having a proximal end and a distal end. The proximal end is mounted to the immersion cooling cabinet below a lower edge of the immersion coolant tank drawer 120b, 120c. The slide bars 552a, 552b may be configured to extend from the proximal end to the distal end away from the immersion cooling cabinet in a direction the immersion coolant tank drawer 120b, 120c slides horizontally. The slide bars 552a, 552b may be configured to engage the immersion coolant tank drawer while the immersion coolant tank drawer slides along the slide bars 552a, 552b. In addition, the engagement elements 554a, 554b may be coupled to the distal end of the slide bars 552a, 552b, respectively and are configured to be load-bearing members.

Each of the paired triangular support brackets 550a, 550b may be pivotally mounted by a hinge (e.g., 160) to the immersion cooling cabinet 110. Unlike the vertically pivoting slide bars (e.g., 152) illustrated in FIGS. 1A-3D, each of the pair of triangular support brackets 550a, 550b illustrated in FIGS. 5A-5C may be configured to pivot laterally, swing from a stowed orientation in which one triangular support bracket (e.g., 550b) overlaps the other triangular support bracket (e.g., 550a). In this way, the triangular support brackets 550a, 550b pivot laterally. Also, the pair of triangular support brackets 550a, 550b may swing in opposite directions to deploy from a stowed orientation. From the stowed orientation, the triangular support brackets 550a, 550b may extend directly away from the immersion coolant tank drawers 120b, 120c into a deployed orientation.

In FIG. 5A, the pairs of triangular support brackets 550a, 550b are shown closed stowed orientation positions. FIG. 5B, the upper pair of the pairs of triangular support brackets 550a, 550b are shown in open deployed positions, with the lower pair are shown in closed stowed positions. FIG. 5C illustrates the one deployed pair of triangular support bracket 550a, 550b supporting an immersion coolant tank drawer 120c in accordance with various embodiments. Unlike other embodiments, the pairs of triangular support brackets 550a, 550b may not prevent the immersion cooling cabinet 110 from tipping when fully loaded. Thus, the immersion cooling cabinet 110 may additionally be bolted or otherwise secured to the floor and/or wall as an anti-tipping measure.

Implementation examples are described in the following paragraphs.

Example 1. A support bracket for an immersion coolant tank drawer configured to slide horizontally in and out of an immersion cooling cabinet, the support bracket comprising a slide bar having a proximal end and a distal end, wherein the proximal end is mounted to the immersion cooling cabinet below a lower edge of the immersion coolant tank drawer, wherein the slide bar is configured to extend from the proximal end to the distal end away from the immersion cooling cabinet in a direction the immersion coolant tank drawer slides horizontally, wherein the slide bar is configured to engage the immersion coolant tank drawer while the immersion coolant tank drawer slides along the slide bar; and an engagement element coupled to the distal end of the slide bar, wherein the engagement element is a load-bearing member.

Example 2. The support bracket of example 1, wherein the proximal end of the slide bar is pivotally mounted to the immersion cooling cabinet enabling the slide bar to pivot between a stowed orientation and a deployed orientation.

Example 3. The support bracket of example 2, wherein the slide bar pivots vertically between the stowed and deployed orientations.

Example 4. The support bracket of example 2, wherein the slide bar pivots horizontally between the stowed and deployed orientations.

Example 5. The support bracket of example 2, wherein the slide bar extends vertically in the stowed orientation and horizontally in the deployed orientation.

Example 6. The support bracket of example 1, wherein the distal end of the slide bar is pivotally mounted to the engagement element enabling the slide bar to pivot relative to the engagement element.

Example 7. The support bracket of example 6, wherein the engagement element includes a support bar that extends from the pivotal mount with the slide bar toward a floor supporting the immersion cooling cabinet.

Example 8. The support bracket of example 1, wherein the slide bar includes a first and second slide bar spaced apart from one another laterally relative to the direction the immersion coolant tank drawer slides.

Example 9. The server mounting bracket of example 1, wherein the engagement element is integrally formed into the distal end of the slide bar and configured to engage an adjacent structure providing support for the slide bar.

Example 10. The server mounting bracket of example 9, wherein the adjacent structure is another immersion cooling cabinet.

Example 11. The server mounting bracket of example 10, wherein the slide bar is configured to engage another immersion coolant tank drawer from the other immersion cooling cabinet while the other immersion coolant tank drawer slides along the slide bar.

Example 12. A support bracket for vertically stacked immersion coolant tank drawers each configured to slide horizontally in and out of an immersion cooling cabinet, the support bracket comprising a first slide bar having a first proximal end and a first distal end, wherein the first proximal end of the first slide bar is mounted to the immersion cooling cabinet below a first edge of a first immersion coolant tank drawer of the vertically stacked immersion coolant tank drawers, wherein the first slide bar is configured to extend from the first proximal end to the first distal end away from the immersion cooling cabinet in a direction the first immersion coolant tank drawer slides horizontally, wherein the first slide bar is configured to engage the first immersion coolant tank drawer while the first immersion coolant tank drawer slides along the first slide bar; a first engagement element coupled to the first distal end of the first slide bar, wherein the first engagement element includes a direct load-bearing contact point to a floor supporting the immersion cooling cabinet; a second slide bar having a second proximal end and a second distal end, wherein the second proximal end is mounted to the immersion cooling cabinet below a lower edge of a second immersion coolant tank drawer of the vertically stacked immersion coolant tank drawers, wherein the second slide bar is configured to extend from the second proximal end to the second distal end away from the immersion cooling cabinet in a direction the second immersion coolant tank drawer slides horizontally, wherein the second slide bar is configured to engage the second immersion coolant tank drawer while the second immersion coolant tank drawer slides along the second slide bar; and a second engagement element coupled to the second distal end of the second slide bar, wherein the second engagement element includes a second direct load-bearing contact point to the first slide bar.

Example 13. The support bracket of example 12, wherein the first proximal end of the first slide bar is pivotally mounted to the immersion cooling cabinet enabling the first slide bar to pivot between a stowed orientation and a deployed orientation.

Example 14. The support bracket of example 13, wherein the first slide bar extends vertically in the stowed orientation and horizontally in the deployed orientation.

Example 15. An immersion cooling system, comprising a first immersion cooling cabinet including two or more first immersion coolant tank drawers vertically stacked, wherein each of the two or more first immersion coolant tank drawers are configured to slide horizontally between a closed orientation within the first immersion cooling cabinet and an open position at least partially outside the first immersion cooling cabinet; a second immersion cooling cabinet including two or more second immersion coolant tank drawers vertically stacked, wherein each of the two or more second immersion coolant tank drawers are configured to slide horizontally between a closed position within the second immersion cooling cabinet and an open position at least partially outside the second immersion cooling cabinet; and a slide bar configured to form a bridge between the first and second immersion cooling cabinets, wherein at least one of the two or more first immersion coolant tank drawers or the two or more second immersion coolant tank drawers are configured to engage and be supported by the slide bar while sliding between the closed and open positions.

Example 16. The immersion cooling system of example 15, where the slide bar includes a first and second slide bar spaced apart from one another laterally relative to a direction in which the first and second immersion coolant tank drawers are configured to slide.

Example 17. The immersion cooling system of example 15, wherein the slide bar is configured to support both one of the two or more first immersion coolant tank drawers and one of the two or more second immersion coolant tank drawers, wherein the first and second immersion coolant tank drawers are disposed directly across from one another.

The foregoing descriptions of systems, devices, and methods are provided merely as illustrative examples and are not intended to require or imply that the steps of the various embodiments must be performed in the order presented. As will be appreciated by one of skill in the art the order of steps in the foregoing embodiments may be performed in any order. Words such as “thereafter,” “then,” “next,” etc. are not intended to limit the order of the steps; these words are used to guide the reader through the description of the methods. Further, any reference to claim elements in the singular, for example, using the articles “a,” “an” or “the” is not to be construed as limiting the element to the singular.

The preceding description of the disclosed embodiments is provided to enable any person skilled in the art to make or use the present invention. Various modifications to these embodiments will be readily apparent to those skilled in the art, and the generic principles defined herein may be applied to other embodiments without departing from the spirit or scope of the invention. Thus, the present invention is not intended to be limited to the embodiments shown herein but is to be accorded the widest scope consistent with the following claims and the principles and novel features disclosed herein.

What is claimed is:

1. A support bracket for an immersion coolant tank drawer configured to slide horizontally in and out of an immersion cooling cabinet, the support bracket comprising:
a slide bar having a proximal end and a distal end, wherein the proximal end is mounted to the immersion cooling cabinet below a lower edge of the immersion coolant tank drawer, wherein the slide bar is configured to extend from the proximal end to the distal end away from the immersion cooling cabinet in a direction the immersion coolant tank drawer slides horizontally, wherein the slide bar is configured to engage the immersion coolant tank drawer while the immersion coolant tank drawer slides along the slide bar; and
an engagement element coupled to the distal end of the slide bar, wherein the engagement element is a load-bearing member.

2. The support bracket of claim 1, wherein the proximal end of the slide bar is pivotally mounted to the immersion cooling cabinet enabling the slide bar to pivot between a stowed orientation and a deployed orientation.

3. The support bracket of claim 2, wherein the slide bar pivots vertically between the stowed and deployed orientations.

4. The support bracket of claim 2, wherein the slide bar pivots horizontally between the stowed and deployed orientations.

5. The support bracket of claim 2, wherein the slide bar extends vertically in the stowed orientation and horizontally in the deployed orientation.

6. The support bracket of claim 1, wherein the distal end of the slide bar is pivotally mounted to the engagement element enabling the slide bar to pivot relative to the engagement element.

7. The support bracket of claim 6, wherein the engagement element includes a support bar that extends from the pivotal mount with the slide bar toward a floor supporting the immersion cooling cabinet.

8. The support bracket of claim 1, wherein the slide bar includes a first and second slide bar spaced apart from one another laterally relative to the direction the immersion coolant tank drawer slides.

9. The support bracket of claim 1, wherein the engagement element is integrally formed into the distal end of the slide bar and configured to engage an adjacent structure providing support for the slide bar.

10. The support bracket of claim 9, wherein the adjacent structure is another immersion cooling cabinet.

11. The support bracket of claim 10, wherein the slide bar is configured to engage another immersion coolant tank drawer from the other immersion cooling cabinet while the other immersion coolant tank drawer slides along the slide bar.

12. A support bracket for vertically stacked immersion coolant tank drawers each configured to slide horizontally in and out of an immersion cooling cabinet, the support bracket comprising:
a first slide bar having a first proximal end and a first distal end, wherein the first proximal end of the first slide bar is mounted to the immersion cooling cabinet below a first edge of a first immersion coolant tank drawer of the vertically stacked immersion coolant tank drawers, wherein the first slide bar is configured to extend from the first proximal end to the first distal end away from the immersion cooling cabinet in a direction the first immersion coolant tank drawer slides horizontally, wherein the first slide bar is configured to engage the first immersion coolant tank drawer while the first immersion coolant tank drawer slides along the first slide bar;
a first engagement element coupled to the first distal end of the first slide bar, wherein the first engagement element includes a direct load-bearing contact point to a floor supporting the immersion cooling cabinet;
a second slide bar having a second proximal end and a second distal end, wherein the second proximal end is mounted to the immersion cooling cabinet below a lower edge of a second immersion coolant tank drawer of the vertically stacked immersion coolant tank drawers, wherein the second slide bar is configured to extend from the second proximal end to the second distal end away from the immersion cooling cabinet in a direction the second immersion coolant tank drawer slides horizontally, wherein the second slide bar is configured to engage the second immersion coolant tank drawer while the second immersion coolant tank drawer slides along the second slide bar; and
a second engagement element coupled to the second distal end of the second slide bar, wherein the second engagement element includes a second direct load-bearing contact point to the first slide bar.

13. The support bracket of claim 12, wherein the first proximal end of the first slide bar is pivotally mounted to the immersion cooling cabinet enabling the first slide bar to pivot between a stowed orientation and a deployed orientation.

14. The support bracket of claim 13, wherein the first slide bar extends vertically in the stowed orientation and horizontally in the deployed orientation.

15. An immersion cooling system, comprising:
a first immersion cooling cabinet including two or more first immersion coolant tank drawers vertically stacked, wherein each of the two or more first immersion coolant tank drawers are configured to slide horizontally between a closed orientation within the first immersion cooling cabinet and an open position at least partially outside the first immersion cooling cabinet;
a second immersion cooling cabinet including two or more second immersion coolant tank drawers vertically stacked, wherein each of the two or more second immersion coolant tank drawers are configured to slide horizontally between a closed position within the second immersion cooling cabinet and an open position at least partially outside the second immersion cooling cabinet; and
a slide bar configured to form a bridge between the first and second immersion cooling cabinets, wherein at least one of the two or more first immersion coolant tank drawers or the two or more second immersion coolant tank drawers are configured to engage and be supported by the slide bar while sliding between the closed and open positions.

16. The immersion cooling system of claim 15, where the slide bar includes a first and second slide bar spaced apart from one another laterally relative to a direction in which the first and second immersion coolant tank drawers are configured to slide.

17. The immersion cooling system of claim 15, wherein the slide bar is configured to support both one of the two or more first immersion coolant tank drawers and one of the two or more second immersion coolant tank drawers, wherein the first and second immersion coolant tank drawers are disposed directly across from one another.
